(19) United States
(12) Patent Application Publication
(10) Pub. No.: US 2025/0338514 A1
(43) Pub. Date: Oct. 30, 2025

(54) DEEP TRENCH CAPACITOR AND METHOD FOR MANUFACTURING THE SAME

(71) Applicant: Shanghai Huahong Grace Semiconductor Manufacturing Corporation, Shanghai (CN)

(72) Inventors: Han YU, Shanghai (CN); Weiran KONG, Shanghai (CN); Binbin MIAO, Shanghai (CN)

(21) Appl. No.: 18/562,494

(22) PCT Filed: Jul. 28, 2023
(86) PCT No.: PCT/CN2023/109718

§ 371 Date: Dec. 12, 2024

(30) Foreign Application Priority Data
Aug. 26, 2022 (CN) 202211032713.7

(51) Int. Cl. H10D 1/00; H10D 1/68

(52) U.S. Cl. CPC H10D 1/042; H10D 1/716

(57) ABSTRACT

The present application provides a deep trench capacitor and a method for manufacturing the same. After stacked oxide layers and polysilicon layers are formed, one-step etching is adopted to etch active area polysilicon to form an opening, and then sidewalls are formed. This changes the previous step-by-step polysilicon-etching sidewall forming process of forming a polysilicon layer, then etching the polysilicon layer to form sidewalls along opposite sidewalls of the polysilicon layer, forming an oxide layer, then forming a polysilicon layer on a surface of the oxide layer, and then etching the polysilicon layer to form sidewalls, thus avoiding leakage caused by step-by-step etching, and realizing a high-density capacitor. Moreover, compared with the traditional DTC layout design, each electrode of the capacitor can be more uniformly led out in the present application, thus improving the performance and yield of the capacitor.

### TECHNICAL FIELD

The present application relates to the field of integrated circuit manufacturing technology, in particular to a deep trench capacitor and a method for manufacturing the same.

### BACKGROUND

Deep Trench Capacitors (DTCs) are widely used in antenna matching, RF filtering, and IC decoupling, especially in applications with height and volume limitations. They still have very high stability and extremely low leakage current at high bias voltages, and play a crucial role in some industrial fields.

Referring to FIG. 1, it illustrates a schematic diagram of a traditional DTC structure. In the formation of the traditional DTC structure, the etching of active area polysilicon adopts step-by-step etching, and oxide layers 11-13, polysilicon layers 14-16 and sidewalls 17-19 are formed alternately in deep trenches. After the formation of the polysilicon layer 14, the polysilicon layer 14 is patterned to expose some of a top surface of the oxide layer 11. Next, sidewalls 17 are formed along opposite sidewalls of the polysilicon layer 14. Then, the oxide layer 12 is formed above the polysilicon layer 14 and the sidewalls 17. The process steps described above for forming the polysilicon layer 14 and the sidewalls 17 are repeated to form the polysilicon layer 15 and sidewall 18s above the oxide layer 12, and form the polysilicon layer 16 and the sidewall 19 above the oxide layer 13. However, this step-by-step etching method easily causes leakage, and with the further development of technology, it poses further challenges to the traditional DTC manufacturing process.

### BRIEF SUMMARY

In view of this, the present application provides a deep trench capacitor and a method for manufacturing the same, so as to improve the manufacturing process of the traditional deep trench capacitor, reduce the occurrence of leakage and improve the device performance.

The present application provides a method for manufacturing a deep trench capacitor, including:
step 1: providing a substrate and forming a deep trench in the substrate;
step 2: forming stacked oxide layers and polysilicon layers in the deep trench and on a surface of the substrate;
step 3: sequentially etching the stacked oxide layers and polysilicon layers to form an opening by using the substrate and the polysilicon layers as etch stop layers;
step 4: forming sidewalls at two ends of the opening;
step 5: depositing a pre-metal dielectric layer, an upper surface of the pre-metal dielectric layer being higher than top surfaces of the sidewalls;
step 6: etching the pre-metal dielectric layer to form contacts and filling the contacts with a metal; and
step 7: forming a metal layer on surfaces of the pre-metal dielectric layer and the contacts, the metal layer being connected to the substrate and the polysilicon layers through the contacts.

Exemplarily, in step 1, the substrate is a silicon substrate.

Exemplarily, in step 1, the number of the deep trench is one or more.

Exemplarily, in step 2, the stacked oxide layers and polysilicon layers are formed alternately.

Exemplarily, in step 2, the stacked oxide layers and polysilicon layers are a stack layer of at least two oxide layers and polysilicon layers.

Exemplarily, in step 2, the thickness of each oxide layer is 75 Å.

Exemplarily, in step 3, the size of the opening is 2 um*0.6 um.

Exemplarily, in step 4, the material of the sidewalls is silicon oxide or silicon nitride.

Exemplarily, in step 6, the contacts include contacts formed above the substrate and contacts formed above the polysilicon layers.

The present application further provides a deep trench capacitor, including:
a substrate;
a Deep Trench Capacitor (DTC) located in the substrate; and
an interconnect structure located above the deep trench capacitor and the substrate, wherein
the deep trench capacitor includes stacked oxide layers and polysilicon layers, and sidewalls formed by etching the stacked oxide layers and polysilicon layers in one step; and
the interconnect structure includes contacts formed in a pre-metal dielectric layer and located above the substrate and the polysilicon layers, and a metal layer located above the contacts.

The present application improves the manufacturing process of the traditional deep trench capacitor. After stacked oxide layers and polysilicon layers are formed, one-step etching is adopted to etch active area polysilicon to form an opening, and then sidewalls are formed. This changes the previous step-by-step polysilicon-etching sidewall forming process of forming a polysilicon layer, then etching the polysilicon layer to form sidewalls along opposite sidewalls of the polysilicon layer, forming an oxide layer, then forming a polysilicon layer on a surface of the oxide layer, and then etching the polysilicon layer to form sidewalls, thus reducing the occurrence of leakage and realizing a high-density capacitor. Moreover, each electrode of the deep trench capacitor formed by adopting the method provided by the present application can be more uniformly led out, thus reducing the parasitic resistance and improving the performance of the capacitor.

### BRIEF DESCRIPTION OF THE DRAWINGS

Through the description of the embodiments of the present application with reference to the drawings below, the above and other purposes, features and advantages of the present application will become clearer.

FIG. 1 illustrates a schematic diagram of a traditional DTC structure.

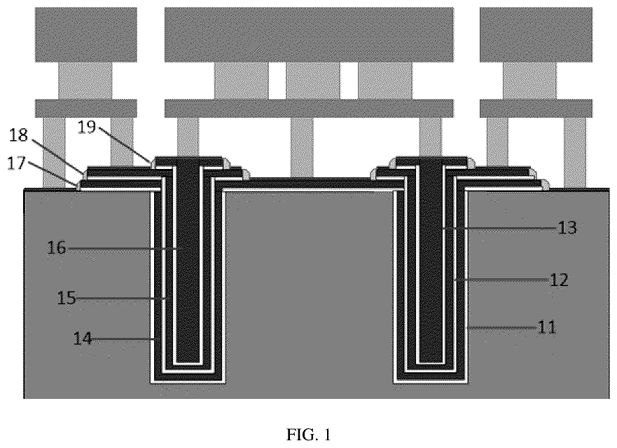

FIG. 2 illustrates a flowchart of a method for manufacturing a deep trench capacitor according to an embodiment of the present application.

FIG. 3 illustrates a structural schematic diagram of a deep trench capacitor according to an embodiment of the present application.

### DETAILED DESCRIPTION OF THE APPLICATION

The present application will be described below based on the embodiments, but the present application is not limited to these embodiments. In the following detailed description of the present application, specific details are described. For those skilled in the art, without the description of these detailed parts, the present application can still be fully understood. In order to avoid confusion with the essence of the present application, the well-known methods, processes, flows, components, and circuits are not described in detail.

In addition, those skilled in the art should understand that the drawings provided here are for description purposes and may not necessarily be drawn to scale.

Unless otherwise specified in the context, words such as “including” and “comprising” in the entire application document shall be interpreted as inclusive rather than exclusive or exhaustive; That is to say, it means “including but not limited to”.

In the description of the present application, it is to be understood that the terms such as “first” and “second” are only used for description purposes and cannot be understood as indicating or implying relative importance. In addition, in the description of the present application, unless otherwise specified, “a plurality of” refers to two or more.

Capacitors are commonly used passive components in very-large integrated circuits, mainly including Polysilicon-Insulator-Polysilicon (PIP), Metal-Insulator-Silicon (MIS) and Metal-Insulator-Metal (MIM). Compared to some other capacitor types within semiconductor Integrated Circuits (ICs), Deep Trench Capacitors (DTCs) exhibit higher power density. Similarly, DTCs are applied to applications such as Dynamic Random-Access Memory (DRAM) storage cells. Some examples of DTCs include multi-layer polysilicon DTCs, which replace discrete capacitors in advanced technology node processes.

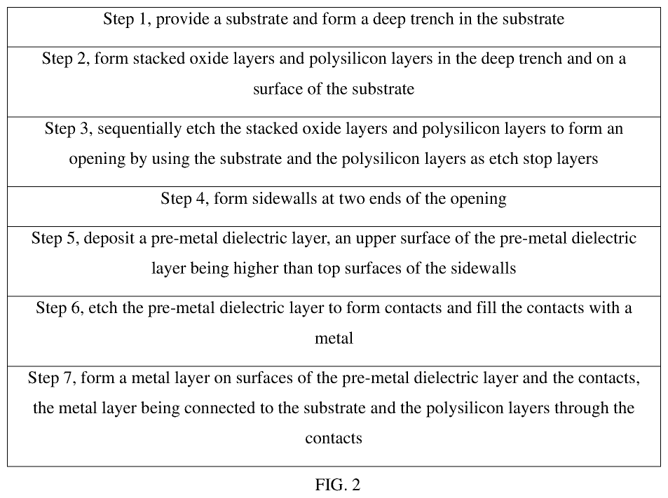

FIG. 2 illustrates a flowchart of a method for manufacturing a deep trench capacitor according to an embodiment of the present application. Referring to FIG. 2, the method includes the following steps:

In step 1, a substrate is provided and a deep trench is formed in the substrate.

The substrate may be monocrystalline silicon, polysilicon, or amorphous silicon. The substrate may also be made of silicon, germanium, gallium arsenide, or silicon germanium compounds. The substrate may also have an epitaxial layer or be a Silicon On Insulator (SOI) substrate. The substrate may also be made of other semiconductor materials. In the embodiment of the present application, the material of the substrate is silicon.

The process of forming a deep trench may include: forming a patterned mask layer on a surface of a substrate, the patterned mask layer defining the width, depth and position of the deep trench; and then etching the substrate by using the patterned mask layer as a mask to form the deep trench. In the embodiment of the present application, the number of the deep trench is one or more.

In step 2, stacked oxide layers and polysilicon layers are formed in the deep trench and on a surface of the substrate.

In the embodiment of the present application, oxide layers and polysilicon layers are formed alternately in the deep trench. The stacked oxide layers and polysilicon layers are a stack layer of at least two oxide layers and polysilicon layers. The polysilicon layers may also be referred to as capacitor electrodes. Each polysilicon layer may be formed by using plating, Physical Vapor Deposition (PVD), ALD, CVD, or a combination thereof. The thickness of each oxide layer is 75 Å.

In step 3, the stacked oxide layers and polysilicon layers are sequentially etched to form an opening by using the substrate and the polysilicon layers as etch stop layers.

In the embodiment of the present application, description will be made by taking a stack layer of three oxide layers and polysilicon layers as an example, respectively including a first oxide layer, a first polysilicon layer, a second oxide layer, a second polysilicon layer, a third oxide layer, and a third polysilicon layer from bottom to top. Specifically, step 3 includes:
etching the third polysilicon layer, the third oxide layer, the second polysilicon layer, the second oxide layer, the first polysilicon layer and the first oxide layer to form an opening located above the substrate by using the substrate as an etch stop layer;
etching the third polysilicon layer, the third oxide layer, the second polysilicon layer and the second oxide layer to form an opening located above the first polysilicon layer by using the first polysilicon layer as an etch stop layer; and
etching the third polysilicon layer and the third oxide layer to form an opening located above the second polysilicon layer by using the second polysilicon layer as an etch stop layer.

In the embodiment of the present application, the size of the opening is 2 um*0.6 um. Compared to the traditional DTC structure, the uniform size of the opening helps to realize a high-density capacitor.

In step 4, sidewalls are formed at two ends of the opening.

In the embodiment of the present application, the material of the sidewalls is silicon oxide or silicon nitride. Exemplarily, ALD or CVD is performed to deposit silicon oxide or silicon nitride in a blanket manner and anisotropic etching is performed at two ends of the opening to form sidewalls. Here, since a plurality of openings are formed in the previous step, a plurality of sidewalls are formed in this step.

Compared to the traditional DTC formation process, after a first polysilicon layer is formed above a first oxide layer, the first polysilicon layer is patterned to expose some of the top surface of the first oxide layer, and then first sidewalls are formed along opposite sidewalls of the first polysilicon layer. Then, a second oxide layer is formed above the first polysilicon layer and the first sidewalls, and the second oxide layer is patterned to remove the portion of the second oxide layer that extends beyond the sidewalls. Next, a second polysilicon layer is formed in a blanket manner above the second oxide layer and the substrate. Then, the second polysilicon layer is patterned to expose some of the top surface of the second oxide layer. Then, second sidewalls are formed along opposite sidewalls of the second polysilicon layer. Then, a third oxide layer is formed above the second polysilicon layer and the second sidewalls. The third oxide layer is patterned to remove the portion of the third oxide layer that extends beyond the second sidewalls. Next, a third polysilicon layer is formed in a blanket manner above the third oxide layer and the substrate. Then, the third polysilicon layer is patterned to expose some of the top surface of the third oxide layer. Then, third sidewalls are formed along opposite sidewalls of the third polysilicon layer. In the present application, after the stacked oxide layers and polysilicon layers are formed in the deep trench and on the surface of the substrate, the etching of polysilicon is performed in one step to form sidewalls, thus not only simplifying the process steps, but also reducing the occurrence of leakage. In addition, the openings and sidewalls are formed uniformly and evenly, which is conducive to the more uniform leading-out of the electrode, thus reducing the parasitic resistance, and improving the yield and performance of the capacitor.

Of course, in the embodiment of the present application, DTC includes three capacitor electrodes. In other embodiments, based on the design requirements of DTC, DTC may include more than or less than three capacitor electrodes.

In step 5, a pre-metal dielectric layer is deposited. An upper surface of the pre-metal dielectric layer is higher than top surfaces of the sidewalls.

In the embodiment of the present application, the pre-metal dielectric layer is Boron Phosphorus Silicate Glass (BPSG), which may be formed by various suitable methods, such as spin coating, CVD, PECVD and ALD.

In step 6, the pre-metal dielectric layer is etched to form contacts and the contacts are filled with a metal.

Contacts are formed in the pre-metal dielectric layer and the contacts are filled with a metal. In the embodiment of the present application, the contacts include contacts formed above the substrate and contacts formed above the polysilicon layer. The metal may be copper, aluminum, tungsten, a combination thereof, or an alloy thereof.

In step 7, a metal layer is formed on surfaces of the pre-metal dielectric layer and the contacts.

In the embodiment of the present application, the metal layer is connected to the substrate and the polysilicon layers through the contacts.

The present application improves the manufacturing process of the traditional deep trench capacitor. After stacked oxide layers and polysilicon layers are formed, one-step etching is adopted to etch active area polysilicon to form an opening, and then sidewalls are formed. This changes the previous step-by-step polysilicon-etching sidewall forming process of forming a polysilicon layer, then etching the polysilicon layer to form sidewalls along opposite sidewalls of the polysilicon layer, forming an oxide layer, then forming a polysilicon layer on a surface of the oxide layer, and then etching the polysilicon layer to form sidewalls, thus reducing the occurrence of leakage and realizing a high-density capacitor. Moreover, each electrode of the deep trench capacitor formed by adopting the method provided by the present application can be more uniformly led out, thus reducing the parasitic resistance and improving the performance of the capacitor.

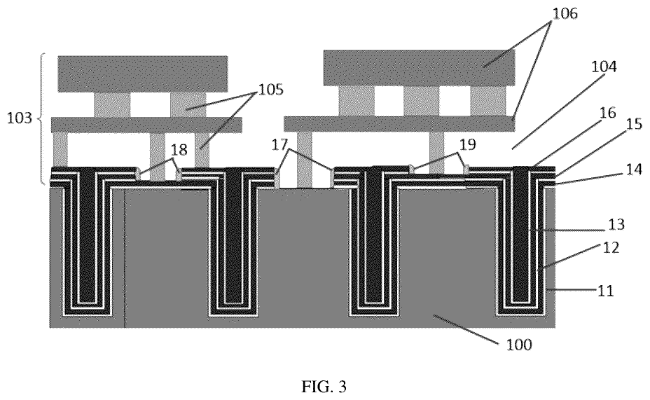

FIG. 3 illustrates a schematic diagram of a deep trench capacitor according to an embodiment of the present application. Referring to FIG. 3, taking three capacitor electrodes as an example, the deep trench capacitor includes a substrate 100, a Deep Trench Capacitor (DTC) located in the substrate 100, and an interconnect structure 103 located above the deep trench capacitor 101 and the substrate 100. The deep trench capacitor includes stacked oxide layers and polysilicon layers, and sidewalls formed by etching the stacked oxide layers and polysilicon layers in one step.

Specifically, the deep trench capacitor includes oxide layers 11-13, polysilicon layers 14-16, and sidewalls 17-19. The interconnect structure 103 includes contacts 105 formed in a pre-metal dielectric layer 104 and located above the substrate and the polysilicon layers, and a metal layer 106 located above the contacts. Of course, it may also include a plurality of pre-metal dielectric layers, contacts and metal layers. Two layers are illustrated therein.

It is to be understood that many other layers may also exist, such as spacing elements and/or other suitable components, which are omitted in the figures for the purpose of simplification.

What are described are only exemplary embodiments of the present application and are not intended to limit the present application. For those skilled in the art, the present application may have various modifications and variations. Any modifications, equivalent replacements, improvements and the like made within the spirit and principle of the present application shall be included within the scope of protection of the present application.

1. A method for manufacturing a deep trench capacitor, comprising:
step 1: providing a substrate and forming a deep trench in the substrate;
step 2: forming stacked oxide layers and polysilicon layers in the deep trench and on a surface of the substrate;
step 3: sequentially etching the stacked oxide layers and polysilicon layers to form an opening by using the substrate and the polysilicon layers as etch stop layers;
step 4: forming sidewalls at two ends of the opening;
step 5: depositing a pre-metal dielectric layer, an upper surface of the pre-metal dielectric layer being higher than top surfaces of the sidewalls;
step 6: etching the pre-metal dielectric layer to form contacts and filling the contacts with a metal; and
step 7: forming a metal layer on surfaces of the pre-metal dielectric layer and the contacts, the metal layer being connected to the substrate and the polysilicon layers through the contacts.

2. The method for manufacturing the deep trench capacitor according to claim 1, wherein in step 1, the substrate is a silicon substrate.

3. The method for manufacturing the deep trench capacitor according to claim 1, wherein in step 1, the number of the deep trench is one or more.

4. The method for manufacturing the deep trench capacitor according to claim 1, wherein in step 2, the stacked oxide layers and polysilicon layers are formed alternately.

5. The method for manufacturing the deep trench capacitor according to claim 1, wherein in step 2, the stacked oxide layers and polysilicon layers are a stack layer of at least two oxide layers and polysilicon layers.

6. The method for manufacturing the deep trench capacitor according to claim 1, wherein in step 2, the thickness of each oxide layer is 75 Å.

7. The method for manufacturing the deep trench capacitor according to claim 1, wherein in step 3, the size of the opening is 2 um*0.6 um.

8. The method for manufacturing the deep trench capacitor according to claim 1, wherein in step 4, the material of the sidewalls is silicon oxide or silicon nitride.

9. The method for manufacturing the deep trench capacitor according to claim 1, wherein in step 6, the contacts comprise contacts formed above the substrate and contacts formed above the polysilicon layers.

10. A deep trench capacitor formed by adopting the method for manufacturing the deep trench capacitor according to claim 1, comprising:
a substrate;
a deep trench capacitor DTC located in the substrate; and
an interconnect structure located above the deep trench capacitor and the substrate, wherein
the deep trench capacitor comprises stacked oxide layers and polysilicon layers, and sidewalls formed by etching the stacked oxide layers and polysilicon layers in one step; and
the interconnect structure comprises contacts formed in a pre-metal dielectric layer and located above the substrate and the polysilicon layers, and a metal layer located above the contacts.
